(19) United States
(12) Patent Application Publication
(10) Pub. No.: US 2009/0140322 A1
(43) Pub. Date: Jun. 4, 2009

(54) Semiconductor Memory Device and Method of Manufacturing the Same

(75) Inventors: Takashi Nakagawa, Tokyo (JP); Yukishige Saito, Tokyo (JP)

Correspondence Address: FOLEY AND LARDNER LLP;SUITE 500, 3000 K STREET NW, WASHINGTON, DC, 20007, US

(73) Assignee: NEC CORPORATION

(21) Appl. No.: 11/992,961

(22) PCT Filed: Oct. 3, 2006
(86) PCT No.: PCT/JP2006/320152

§ 371 Date: Oct. 15, 2008

(30) Foreign Application Priority Data
Oct. 3, 2005 (JP) 2005-289522

(51) Int. Cl. H01L 29/78; H01L 21/336

(52) U.S. Cl. 257/324; 438/287; 257/E29.255; 257/E21.409

(57) ABSTRACT

A first insulation film (silicon dioxide film) and a second insulation film (aluminum oxide film) are laminated on a surface of a silicon substrate in this order to form a gate insulation film. At least one element (aluminum) of elements, which constitutes the second insulation film but is different from elements commonly contained in the whole area of the first insulation film, is caused to be contained in a part of the first insulation film, whereby a charge trapping site region is formed in the first insulation film.

### TECHNICAL FIELD

The present invention relates to a nonvolatile semiconductor memory device and a method of manufacturing the same, and particularly, the present invention relates to a nonvolatile semiconductor memory device, in which a nonvolatile memory device has no floating gate and charge trapping is carried out in a gate insulation film of an insulation film having a laminated structure, and a method of manufacturing the same.

### BACKGROUND ART

When nonvolatile memory devices are roughly classified, there are a Floating Gate (FG) type in which a conductive film such as polysilicon that is embedded in a gate insulation film is used as means for trapping electrical charge, a Metal Nitride Oxide Semiconductor (MNOS) type and a Metal Oxide Nitride Oxide Semiconductor (MONOS) type in which an insulating film such as a silicon nitride film that is laminated in a gate insulation film is used as the means for trapping electrical charge.

Since the FG type uses polysilicon or the like as a charge accumulation layer, an energy barrier against the gate insulation film becomes large, and a leak of trapped charge to a semiconductor substrate surface side and/or a gate electrode side becomes small. On the other hand, since the MNOS and MONOS types accumulate charge in the laminated gate insulation film, an energy barrier becomes small. Thus, the FG type generally has a more superior storage retention characteristic at high temperature than those of the MNOS type and the MONOS type.

However, there is a problem that in the FG type, a silicon dioxide film between a FG portion and a semiconductor substrate surface is to be thinned in view of charge retention capability. When Fowler-Nordheim (FN) tunnel injection is carried out into a silicon dioxide film of 10 nm or thinner, a leak current, called Stress Induced Leakage Current (SILC), occurs in a low electric field region, and all the charge accumulated in the FG is then lost through this leak path. Thus, thinned tunnel oxide film in the FG type leads to 8 nm in view of the charge retention capability because of occurrence of the SILC. Therefore, in the FG type, it is difficult to achieve a balance between decrease in operating voltage due to miniaturization and maintenance of retention capability.

On the other hand, in the MNOS and MONOS types, a charge trapping site serving to accumulate charge exists in an insulation film including them in a space discretization manner. For this reason, even though a leak path is generated due to the SILC in the similar manner to the FG type, local charge around the leak path is merely lost, and therefore, this does not lead to disappearance of nonvolatility in the whole device. Thus, a thinned silicon dioxide film in the FG type can be made between a charge retention layer and a semiconductor substrate surface. As a result, decrease in operating voltage of the device due to the thinned film can be reduced as compared with the FG type.

Recently, in view of the miniaturization described above, MNOS type and MONOS type nonvolatile semiconductor memory devices attract attention with the aim of further high integration of a semiconductor memory device.

### CONVENTIONAL EXAMPLE 1

The MNOS type generally has a laminated structure constructed from a silicon dioxide film as a first insulation film and a silicon nitride film as a second insulation film from a surface side of a semiconductor substrate. The silicon dioxide film as the first insulation film prevents accumulated charge from leaking out to a substrate side. The silicon nitride film as the second insulation film has a charge trapping function, and prevents accumulated charge from leaking out to a gate electrode side (for example, see IEDM Technical Digest (2004) (2004 International Electron Device Meeting Technology Digest) pp. 885-888, FIGS. 1 and 9 (Non-Patent Document 1); hereinafter, referred to as “Conventional Example 1”).

FIG. 17 is a sectional view showing a structure of the MNOS type nonvolatile memory device published by Non-Patent Document 1. In this Conventional Example 1, in a memory device that includes a gate electrode 55 and a control gate 50 on a silicon substrate 51 and a source/drain region 58 in a surface region of the silicon substrate 51, a silicon dioxide film of 4 nm is used as a first insulation film 53, and a silicon nitride film of 26 nm is used as a second insulation film 54.

FIG. 18 is a drawing in which a charge retention characteristic of the device obtained by this Conventional Example 1 is evaluated and a retention temperature dependent property relating to time variation in Vth when charge is written into the device is examined by respectively taking time and threshold value (Vth) to a horizontal axis and a longitudinal axis. By focusing attention on Vth at 150° C. of FIG. 18, threshold voltage after 3×10⁸ sec. (10 years) is reduced to half or lower, that is, about 44 of initial Vth.

### CONVENTIONAL EXAMPLE 2

On the other hand, the MONOS type generally has a laminated structure constructed from a silicon dioxide film as a first insulation film, a silicon nitride film as a second insulation film and a silicon dioxide film as a third insulation film from a surface side of a semiconductor substrate. The silicon dioxide film as the first insulation film prevents accumulated charge from leaking out to the semiconductor substrate as well as the MNOS type. The silicon nitride film as the second insulation film functions as a charge accumulation layer. The silicon dioxide film as the third insulation film prevents accumulated charge from leaking out to a gate electrode side as a barrier layer (for example, see Japanese Patent Application Publication No. 2004-221448, FIGS. 1 and 20 (Patent Document 1); hereinafter, referred to as “Conventional Example 2”).

The MNOS type causes the second silicon nitride film to have a charge trapping function and a function to prevent diffusion of the charge to the gate electrode side, while the MONOS type causes the second silicon nitride film and the third silicon dioxide film to have the respective functions independently.

FIG. 19 is a sectional view showing a structure of a MONOS type nonvolatile memory device disclosed in Patent Document 1. The device of this Conventional Example 2 includes a gate electrode 65 interposed between gate sidewalls 67 on a silicon substrate 61, and a source/drain region 68 in a surface region of the silicon substrate 61. The device is a MONOS type nonvolatile memory device having a silicon dioxide film of thickness 1.8 nm as a first insulation film, a silicon nitride film of thickness 20 nm as a second insulation film and a silicon dioxide film of thickness 3.5 nm as a third insulation film on the silicon substrate.

FIG. 20 is a drawing in which in the device obtained by this Conventional Example 2a retention characteristic at 85° C. relating to time variation in Vth when charge is written into the device is examined by respectively taking time and Vth to a horizontal axis and a longitudinal axis. As shown in FIG. 20, Vth after 3×10⁸ sec. which is extrapolated from experimental values is reduced to about 60 with respect to the initial value.

### CONVENTIONAL EXAMPLE 3

Further, devices to which an insulation film made of material other than that of the conventional silicon nitride film is applied as a charge accumulation layer are proposed (for example, see Japanese Patent Application Publication No. 2004-158810 (Patent Document 2), Japanese Patent Application Publication No. 2002-368142 (Patent Document 3), and Japanese Patent Application Publication No. 5-121764 (Patent Document 4)). In Patent Documents 2, 3, it is disclosed that an aluminum oxide film is used in place of the silicon nitride film in the MONOS type nonvolatile device. Further, in Patent Document 4, it is disclosed that a mixed film constructed from a high-permittivity insulation film and a formless insulation film is used in place of the silicon nitride film. The features of these technologies have an advantage that charge retention capability can be improved by using the insulation film having a charge trapping level deeper than that of the silicon nitride film that is used as the conventional charge trapping layer.

However, in the above technologies, there are respectively problems as follows.

First, as disclosed in Non-Patent Document 1 and Patent Document 1, in the case where the film thickness of the charge accumulation layer and the barrier layer is 20 nm or thicker, retention capability is not sufficient at high temperature of 85° C. or 150° C. Thus, there is a problem that in order to ensure a charge trapping amount and charge retention capability, a thinned gate insulation film including the charge accumulation layer and the barrier film cannot be made.

Second, in the case where a charge accumulation layer in which charge trapping sites exist evenly is used, as disclosed in Patent Documents 3, 4 and 5, there is a problem that charge retention capability is reduced due to an influence of electric potential distribution formed by trapped charge even when a charge trapping level becomes deep.

### DISCLOSURE OF THE INVENTION

A task of the present invention is to solve the problems of the prior art described above, and it is an object to be allowed to achieve a balance between a thinned insulation film and charge retention capability at high temperature in a nonvolatile memory device having a laminated structure of an insulation film as means for trapping charge, and to relieve electric potential distribution by trapped charge.

In order to achieve the above object, according to the present invention, there is provided a nonvolatile semiconductor memory device including a plurality of nonvolatile memory devices, each nonvolatile memory device having a first insulation film and a second insulation film as a gate insulation film, the first insulation film being formed so as to contact with a surface of a semiconductor substrate, the second insulation film being formed so as to contact with the first insulation film, wherein at least one element of elements that constitute the second insulation film is contained in at least a region of the first insulation film that contacts with the second insulation film as a trapping site for charge.

Further, it is preferable that density of an element that is at least one element of elements constituting the second insulation film and different from elements commonly included in the whole area of the first insulation film becomes the highest on a surface of the first insulation film that contacts with the second insulation film, and becomes lower toward the semiconductor substrate surface substantially in accordance with Gaussian distribution. Moreover, it is preferable that the first insulation film is a silicon dioxide film, the second insulation film is formed from an insulation film containing aluminum, and the element to become the charge trapping site is constituted from aluminum.

Further, in order to achieve the above object, according to the present invention, there is provided a method of manufacturing a nonvolatile semiconductor memory device, the nonvolatile semiconductor memory device including a plurality of nonvolatile memory devices, each nonvolatile memory device having a first insulation film and a second insulation film as a gate insulation film, the first insulation film being formed so as to contact with a surface of a semiconductor substrate, the second insulation film being formed so as to contact with the first insulation film, the method including: forming a gate insulation film; forming a gate electrode; and forming a source/drain region, wherein the forming the gate insulation film including: (1) forming a first insulation film on the surface of the semiconductor substrate; (2) forming a second insulation film on the first insulation film; and (3) introducing an element that does not constitute the first insulation film but constitutes the second insulation film to the first insulation film.

Further, it is preferable that the semiconductor substrate is a silicon substrate, and the (1) step described above is a step of forming a silicon dioxide film by means of thermal oxidation. Moreover, it is preferable that the (3) step described above is a step of diffusing the element to become the charge trapping site from the second insulation film to the first insulation film by carrying out the thermal treatment.

### EFFECTS OF THE INVENTION

According to the present invention, it is possible to select material of the first insulation film and an element of the charge trapping site independently. Thus, according to the present invention, material having a wide band gap such as a silicon dioxide film can be selected as the first insulation film, and it is possible to select an element that forms a depth level as the element to become the charge trapping site. Therefore, it is possible to improve a charge retention characteristic of the nonvolatile semiconductor memory device. In addition, according to the present invention, the element to become the charge trapping site can be contained intensively in a region of the first insulation film near the second insulation film. Therefore, according to the present invention, electrode distribution due to the trapped charge in the first insulation film can be relieved, and the charge retention characteristic can be improved further.

### BRIEF DESCRIPTION OF THE DRAWING

FIG. 1(a) is a sectional view of a semiconductor memory device according to an embodiment of the present invention, and FIG. 1(b) is a drawing showing density distribution of diffusion element in a gate insulation film portion;

FIG. 2 is an energy band view showing charge trapping levels formed in the memory devices of the present invention and Conventional Example;

FIG. 3 is a drawing showing electric potential distribution that is formed by trapped charge in the memory devices of the present invention and Conventional Example;

FIGS. 4(a) to 4(e) are sectional views of process sequence showing a method of manufacturing according to embodiments of the present invention as Example 1;

FIG. 5 is a drawing showing a nonvolatile characteristic of the device obtained by Example 1 of the present invention;

FIG. 6 is a drawing showing a charge retention characteristic at 150° C. of the device obtained by Example 1 of the present invention;

FIG. 7 is a drawing showing a SIMS analysis result of the device obtained by Example 1 of the present invention;

FIG. 8 is a drawing showing a dependent property of an aluminum oxide film thickness of a Vth shift amount with respect to charge trapping site density of the device obtained by Example 1 of the present invention;

FIG. 9 is a drawing showing a retention characteristic at 150° C. of the device obtained by Example 1 of the present invention;

FIG. 10 is a sectional view of a gate insulation film portion of a semiconductor memory device according to Example 2 of the present invention;

FIG. 11 is a drawing showing a nonvolatile characteristic of the device obtained by Example 2 of the present invention;

FIG. 12 is an ampere-volt curve showing a leak characteristic of the device obtained by Example 2 of the present invention;

FIG. 13 is a sectional view of a gate insulation film portion of a semiconductor memory device according to Example 3 of the present invention;

FIG. 14 is a drawing showing a retention characteristic at 150° C. of the device obtained by Example 3 of the present invention;

FIG. 15 is a sectional view of a gate insulation film portion of a semiconductor device according to Comparative Example;

FIG. 16 is a drawing showing a writing characteristic of the device of Comparative Example and the semiconductor memory device of the present invention;

FIG. 17 is a sectional view of Conventional Example 1;

FIG. 18 is a retention characteristic view of Conventional Example 1;

FIG. 19 is a sectional view of Conventional Example 2; and

FIG. 20 is a retention characteristic view of Conventional Example 2.

### BEST MODE FOR CARRYING OUT THE INVENTION

Embodiments of the present invention will now be described with reference to drawings in detail.

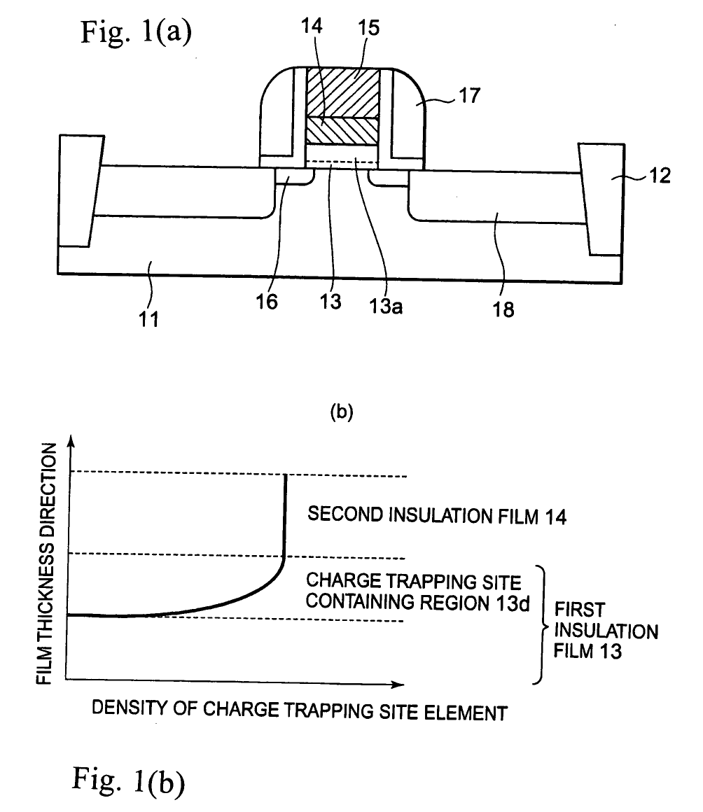

FIG. 1(a) is a sectional view of a memory device according to an embodiment of the present invention. A device isolation region 12 is formed on a silicon substrate 11. A gate electrode 15 is formed on a region divided by device isolation regions 12 through a first insulation film 13 and a second insulation film 14. A gate sidewall 17 made from an insulation film is formed on a side surface of the gate electrode 15. An extension diffusion layer 16 and a source/drain region 18 are formed in a substrate surface region of both sides of the gate electrode 15. A charge trapping site containing region 13a into which an element constituting the second insulation film 14 is introduced as a charge trapping site is formed in the first insulation film 13.

FIG. 1(b) is a density distribution view in a gate insulation film portion of an element that becomes or can become the charge trapping site, of the elements that constitute the second insulation film 14. Density of this element in the first insulation film 13 becomes maximum at a portion of the first insulation film 13 that contacts with the second insulation film 14, and is lowered substantially in accordance with Gaussian distribution toward the silicon substrate 11. Further, this element is not contained in a region of the first insulation film 13 near the silicon substrate 11.

The present invention is based on a new knowledge that an element that is not contained commonly in the first insulation film and is at least one element of elements constituting the second insulation film is caused to be contained in the region of the first insulation film in which the first insulation film contacts with the second insulation film, whereby it is possible to accumulate the charge. This phenomenon will be described by taking the case where a silicon dioxide film and an aluminum oxide film are respectively used as the first insulation film 13 and the second insulation film 14 in FIG. 1 as an example. In a region in which the silicon dioxide film contacts with the aluminum oxide film, an aluminum element that is a constituent element of aluminum oxide is contained in the silicon dioxide film by means of, for example, thermal diffusion. In this way, it is based on a new principle that the charge trapping site containing region 13a is formed in the silicon dioxide film, and the aluminum oxide film (second insulation film 14) serves as a barrier film, whereby charge of the trapping site can be accumulated.

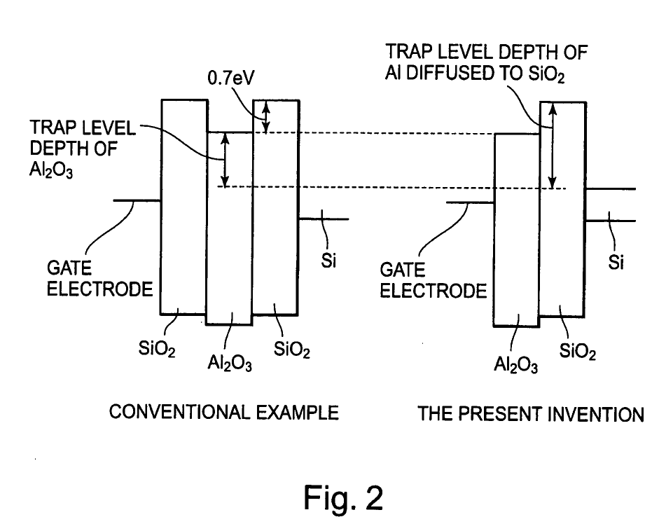

A schematic view of a charge trapping level formed in the memory device of the present invention is shown in FIG. 2 as compared with Conventional Example. Here, Conventional Example shows a charge trapping level of the case where a silicon dioxide film, an aluminum oxide film and a silicon dioxide film are respectively used as a first insulation film, a second insulation film and a third insulation film. In Conventional Example, the charge trapping level is formed in the aluminum oxide film, while in the device of the present invention the charge trapping level is contained in the silicon dioxide film that is the first insulation film. For this reason, as compared with the prior art, a difference level at a lower end of a conduction band between silicon oxide and aluminum oxide becomes deep, whereby the charge retention capability can be improved. Moreover, in the present invention, the aluminum oxide film having a high dielectric constant is used as a supply source of the aluminum element to be contained in the silicon dioxide film and the insulation film that functions as a barrier film. For this reason, as compared with the prior art in which a silicon dioxide film is used as a barrier film, it is possible to reduce a film thickness converted by an oxide film (Effective Oxide Thickness, which is abbreviated as “EOT”). In addition, density of the charge trapping site to be formed can be controlled by density of aluminum element contained in the silicon dioxide film. Thus, since a trappable charge amount can be ensured without increasing a film thickness of the charge accumulation layer, it can become means for thinning the gate insulation film. Further, a shift amount of the Vth of the nonvolatile semiconductor memory device manufactured by the present invention is determined by density of the aluminum element to be contained and the film thickness of the aluminum oxide film. In view of decrease in the EOT in the gate insulation film of the device, it is desirable that a film thickness of the aluminum oxide is set to 30 nm or thinner, and more desirably, it is set to 10 nm or thinner. In such a case, in order to achieve a Vth shift of 0.5V or higher, it is desirable that the aluminum element of 1×10¹² atoms per 1 cm² is contained, and more desirably the aluminum element of 5×10¹² or more atoms per 1 cm² is contained. Further, upper limit of the density of the aluminum element to be contained is determined by density of the aluminum element contained in the aluminum oxide, and the density becomes 5×10¹⁵ atoms/cm².

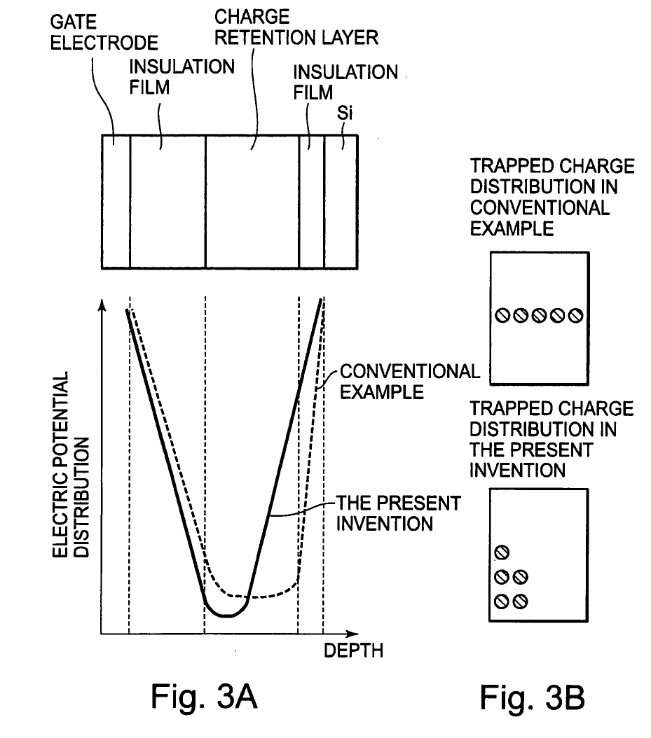

Next, a schematic view of electric potential distribution in the gate insulation film, which is formed by trapped charge, is shown in FIG. 3(a), and a schematic view of trapped charge distribution in each of the charge trapping layers formed by the prior art and the present invention is shown in FIG. 3(b). In Conventional Example, trapping sites for charge exist evenly in the charge trapping layer. For this reason, the electric potential distribution in the first insulation film becomes precipitous as shown in FIG. 3(a), and there is a fear that a leak toward the substrate occurs. On the other hand, in the present invention, distribution of the charge trapping site is controlled so that the density becomes lower from an interface between the first insulation film and the second insulation film to the substrate side as shown in FIG. 1(b). This causes a slope of the electric potential distribution by the trapped charge toward the semiconductor substrate surface to become more gradual than that in Conventional Example by reflecting the distribution of the trapped charge, and a leak of the charge toward the semiconductor substrate is prevented, whereby the charge retention capability is improved. Further, in order to relieve sharpness of a slope of the electric potential distribution without varying the total amount of the charge trapping site with respect to the charge trapping site in Conventional Example, it is desirable that its density distribution is distributed so that the density becomes the highest at a surface in which the first insulation film contacts with the second insulation film, and the density becomes lower toward the semiconductor substrate surface side substantially in accordance with Gaussian distribution. A shift amount of the Vth of the nonvolatile semiconductor memory device of the present invention can be increased in proportion to the film thickness of the second insulation film between the charge trapping site and the gate electrode. Namely, in the case where two devices each having the same film thickness of a charge retention layer and the same charge trapping site amount are compared, the device in which a distance between the charge trapping site and the gate electrode is separated can obtain larger Vth shift amount. However, electric potential distribution by the trapped charge formed in the first insulation film becomes more precipitous, and deterioration of the retention capability occurs. Thus, Gaussian distribution is the most effective as density distribution of the charge trapping site that can achieve a balance between securing of a shift amount of the Vth and retention capability. Further, in the case where an aluminum element is diffused in the whole region toward a film thickness direction of the silicon dioxide film that is the first insulation film, a function to prevent accumulated charge from leaking out to the semiconductor substrate surface side is lost. Therefore, it is important that a diffusion length of the aluminum element to be diffused is required to be reduced less than the film thickness of the silicon dioxide film that is the first insulation film, and the diffusion length is controlled depending on the film thickness of the silicon dioxide film.

Such a control of density and density distribution can be realized by temperature and time of thermal treatment after a laminated structure of a silicon dioxide film and an aluminum oxide film is formed, for example. More specifically, in the nitrogen atmosphere or the oxygen atmosphere, in order to contain the aluminum element in the silicon dioxide film, it is desirable that the temperature range is 700° C. or higher, and more desirably it is 900° C. or higher. Further, in order to make the diffusion length of the aluminum element thinner than the film thickness of the silicon oxide film to be diffused, it is desirable that it is implemented in the temperature range of 1,200° C. or lower, and more desirably it is implemented in the temperature range of 1,100° C. or lower. Moreover, it is also desirable that time when the thermal treatment is implemented is in the range of 10 sec. to 600 sec. Furthermore, the density of the aluminum element to be contained can be controlled by means of composition of aluminum and oxygen of the aluminum oxide.

Here, although the aluminum element is diffused by the thermal diffusion method, it is not limited to this, and it may be formed by diffusing aluminum into the silicon dioxide film by means of a sputtering implantation method. In this case, when an aluminum oxide film is deposited by means of the sputtering method, an implantation depth and an amount thereof can be controlled by electric power and pressure at a deposit process.

As described above, although the case where the aluminum oxide film is used as the second insulation film, it is not limited to this, and an AlHfO film may be used. In this case, since it can heighten a dielectric constant compared with the aluminum oxide film, it is effective to decrease the EOT of the gate insulation film further. Further, an AlSiO film may be used with the aim of inhibiting crystallization of the second insulation film at the thermal diffusing step. In each case, since the aluminum element is contained in the second insulation film, it is possible to obtain the similar effect to the case of using the aluminum oxide film.

Moreover, the aluminum oxide that contains the aluminum element as a diffusion source of the aluminum element is used in this manner, it is possible to avoid the problem that trapped charge is lost though a remaining aluminum film as compared with the case where a continuous film of aluminum is used as the diffusion source.

### EXAMPLE 1

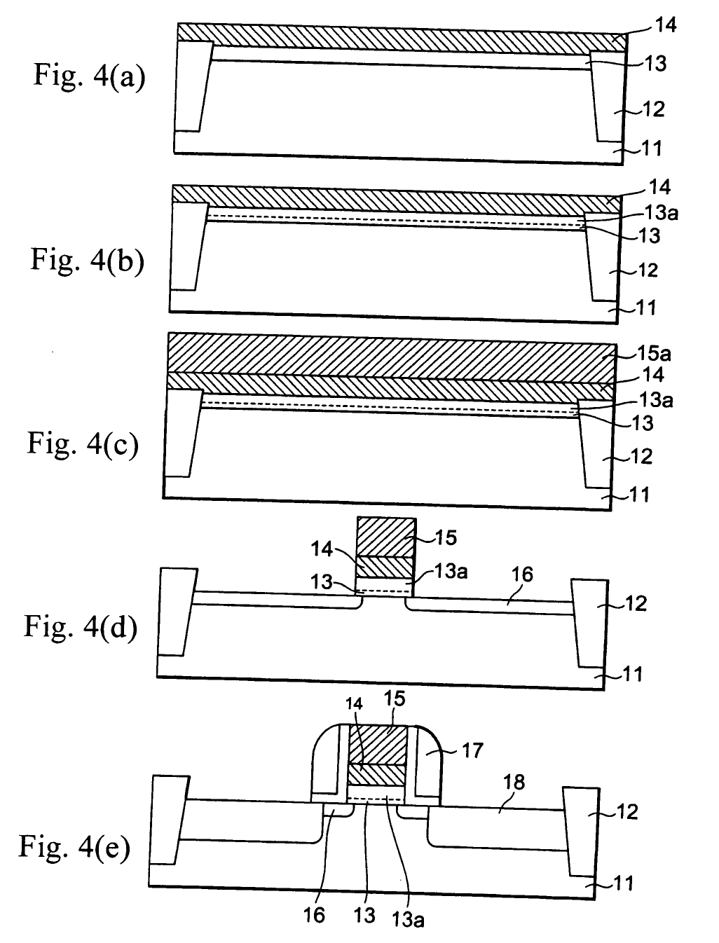

FIGS. 4(a) to 4(e) are sectional views of a process sequence showing a method of manufacturing a device according to the embodiment of the present invention as Example 1. A device isolation region 12 is first formed on a surface of a silicon substrate 11 using a Shallow Trench Isolation (STI) technology. Subsequently, a silicon dioxide film is formed on a silicon substrate surface in which device separation is made as a first insulation film 13 by means of a thermal oxidation method. A desired film thickness of the silicon dioxide film is in the range of 3 nm to 20 nm, and more preferably it is in the range of 5 nm to 15 nm. This is because it is difficult to ensure a region where an element to become a charge trapping site is introduced when this element is introduced in the case where it becomes 3 nm or thinner. Further, this is because it leads to increase of the EOT in the case where it exceeds the range of 15 nm to 20 nm. Subsequently, an aluminum oxide film is formed as a second insulation film 14 in the range of 0.5 nm to 30 nm by a Metal Organic Chemical Vapor Deposition (MOCVD) method. For example, Al (CH₃)₃ and H₂O are respectively used as organic metal material and an oxidizing agent, and an aluminum oxide film is formed by alternately supplying Al (CH₃)₃ and H₂O on the substrate subjected to heating at 300° C. (FIG. 4(a)). Further, ozone may be used as the oxidizing agent in place of H₂O. Moreover, by controlling partial pressure of the oxidizing agent to be introduced, an Atomic Layer Deposition (ALD) method may be used. Further, a Physical Vapor Deposition (PVD) method such as sputtering may be used. Furthermore, by controlling a flow ratio of the organic metal material and the oxidizing agent and oxygen partial pressure at sputtering, composition of aluminum and oxygen in the aluminum oxide film may be varied. By varying the composition, density of aluminum to be diffused in the silicon dioxide film that is the first insulation film can be controlled. For example, by forming the aluminum oxide film having the composition containing more aluminum than stoichiometric composition of aluminum oxide, more aluminum element can be diffused.

Next, the aluminum element contained in the aluminum oxide film that is the second insulation film 14 is thermally diffused into the silicon dioxide film that is the first insulation film 13 by means of the thermal treatment, whereby a charge trapping site containing region 13a is formed in the first insulation film 13 (FIG. 4(b)). Thus, the aluminum element is diffused from the aluminum oxide film 14 to the silicon dioxide film 13 in accordance with a Gaussian distribution expression made of a function of a diffusion constant and time determined by temperature. For this reason, the most desirable density distribution is automatically obtained in the present invention. For example, thermal treatment is implemented at a temperature range of 700° C. to 1,100° C. in the nitrogen atmosphere or the oxygen atmosphere. In particular, it is preferable that a temperature range is between 800° C. and 1,100° C. The thermal treatment time is implemented in the range of 1 sec. to 600 sec. In particular, it is preferable to be in the range of 30 sec. to 600 sec. However, crystallization of the aluminum oxide film occurs at 900° C. or higher, and the function as the barrier film is deteriorated due to a grain boundary. Further, a diffusion amount and a diffusion distance of the aluminum element may be selected by a film thickness of the silicon dioxide film, a film thickness of the aluminum oxide film and a control range of Vth in the device thus required.

In this regard, although the aluminum oxide film is used as the second insulation film here, it is not limited to this, and an AlHfO film may be formed in place of the aluminum oxide film. AlHfO can be formed by a MOCVD method or an ALD method using Al (CH₃)₃ and Hf[N(C₂H₅)₂]₄ as organic metal material and H₂O or ozone as an oxidizing agent. By diffusing an Al element contained in AlHfO into the silicon dioxide film, it is possible to obtain the similar effect to that in the case of aluminum oxide. Further, by using the AlHfO, the dielectric constant can be heightened, and the EOT can be decreased.

Further, in the similar manner, an AlSiO film may be formed in place of the aluminum oxide film. AlSiO can be formed by a MOCVD method or an ALD method using Al (CH₃)₃ and HSi[N(CH₃)₂]₃ as organic metal material and H₂O or ozone as an oxidizing agent. By diffusing an Al element contained in AlSiO into the silicon dioxide film, it is possible to obtain the similar effect to that in the case of aluminum oxide. Moreover, by using AlSiO, crystallization can be inhibited, and the aluminum element can be diffused at higher temperature.

Furthermore, although the aluminum element contained in the second insulation film 14 is diffused into the silicon dioxide film that is the first insulation film 13 by means of thermal diffusion here, it is not limited to this, and diffusion of aluminum into the silicon dioxide film may be implemented by a sputtering implantation method. More specifically, when the aluminum oxide film is deposited by means of sputtering, an implantation amount and a depth of the aluminum element into the silicon dioxide film can be controlled by accurately controlling sputtering electrical power and pressure at the deposition. For example, by heightening sputtering electrical power at low pressure in an initial step of deposition, the aluminum element of low density can be implanted deeply. Then, by controlling the sputtering power so as to become lower while gradually heightening pressure, the aluminum element of high density can be implanted in a shallow region. Thus, the aluminum element can be contained in the silicon dioxide film with density and density distribution similar to the case of the thermal diffusion by means of the sputtering implantation method.

Next, a polysilicon film 15a having a thickness of 150 nm for forming a gate electrode is deposited (FIG. 4(c)). The polysilicon film 15a is then subjected to patterning to form a gate electrode 15 using a lithography technology and a Reactive Ion Etching (RIE) technology. Subsequently, ion implantation is implemented using the gate electrode 15 as a mask to form an extension diffusion layer 16 with respect to the gate electrode 15 (FIG. 4(d)).

Next, a silicon nitride film and a silicon dioxide film are deposited in turn, and then etched back to form a gate sidewall 17. At this state, ion implantation is implemented again, and a source/drain region 18 is then formed through activation annealing (FIG. 4(e)).

Hereinafter, results to examine a property of the device manufactured as Example 1 will be described.

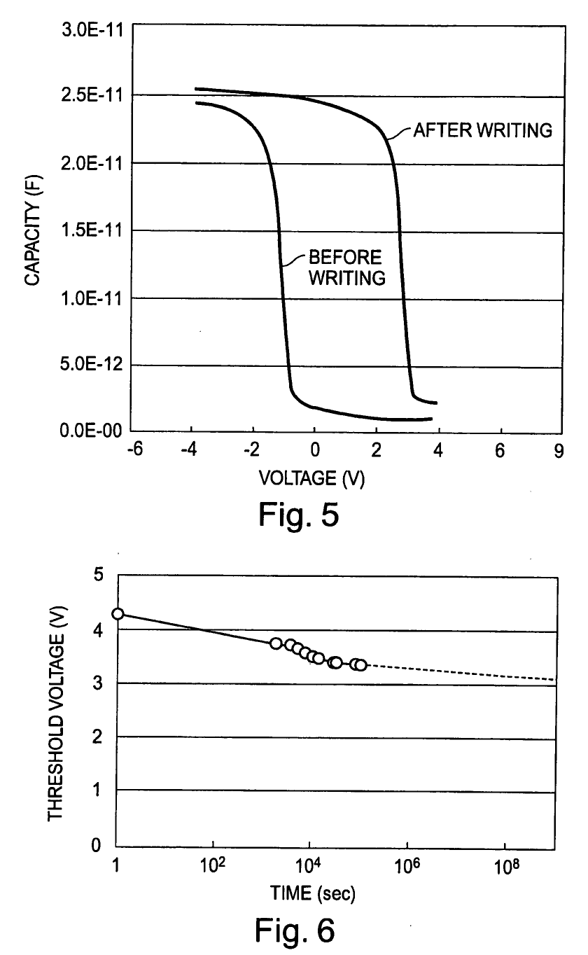

FIG. 5 is a capacity-voltage characteristic (C-V characteristic) of the device obtained in Example 1 before and after writing. It is seen from FIG. 5 that the capacity-voltage characteristic is widely shifted before and after the writing and a nonvolatile operation can thus be achieved.

FIG. 6 is a drawing in which time variation in Vth when charge is written into the device obtained by Example 1 is examined by respectively taking time and Vth to a horizontal axis and a longitudinal axis. Further, the time in the horizontal axis is time when the device is kept in a high temperature bath of 150° C. It is seen from FIG. 6 that charge is retained even at high temperature of 150° C. and the Vth after 3×10⁸ sec. (10 years) which is extrapolated from experimental values is maintained at a value of 72 with respect to the initial value. Thus, the device proposed in the present invention can not only decrease the EOT as compared with Conventional Example 1 and Conventional Example 2, but also have more excellent retention capability than that in Conventional Examples.

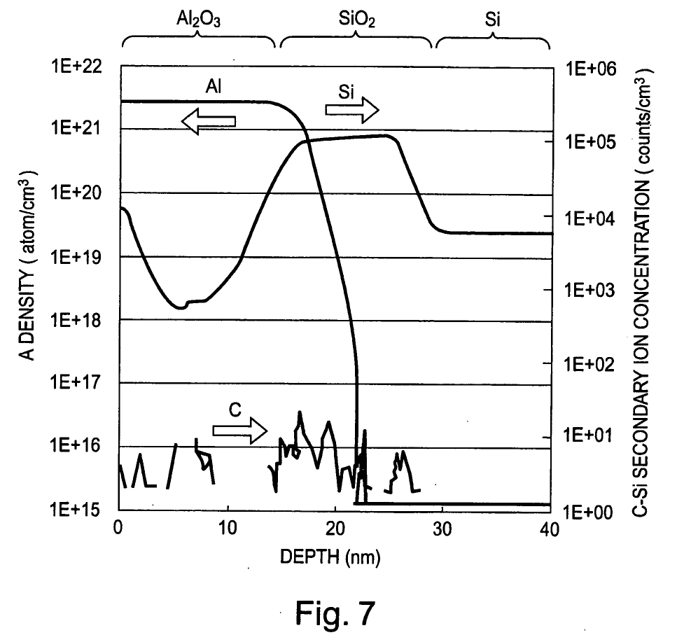

FIG. 7 shows results of Secondary Ion Mass Spectrometry (hereinafter, abbreviated as “SIMS”) for the device obtained by Example 1. It is seen from FIG. 7 that in the device indicating a nonvolatile operation the aluminum element is diffused in the silicon dioxide film and its density distribution is distributed so as to become lower toward the semiconductor substrate direction. Further, here, when density of the diffused aluminum element is examined, it is 3×10¹³ atoms per 1 cm², and this value is the same as a value of charge trapping density that is calculated from a Vth shift amount of the device.

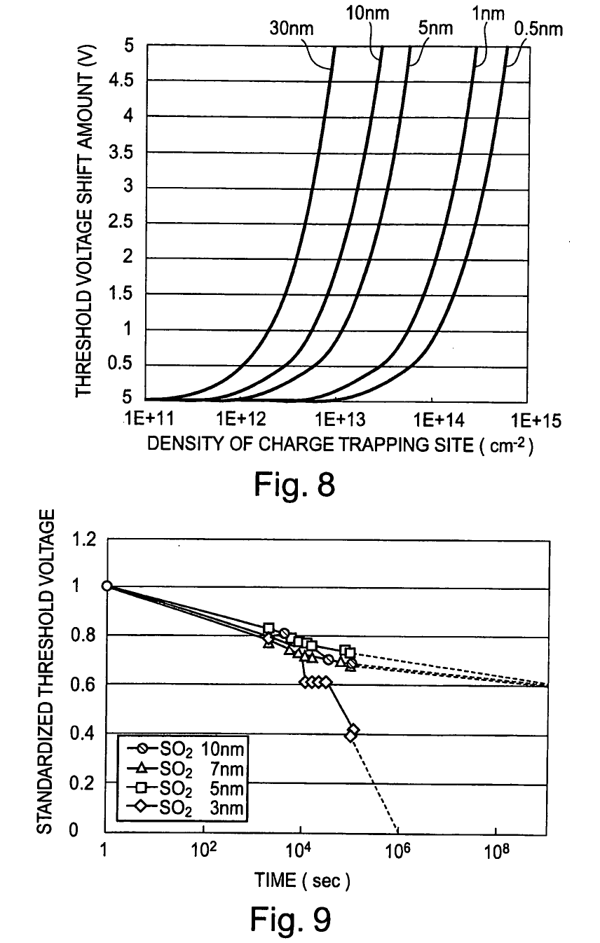

Next, effects presented to a device property by a film thickness of the aluminum oxide film that is the second insulation film and density of the charge trapping site formed in the silicon dioxide film that is the first insulation film will be described. FIG. 8 is a drawing in which a film thickness dependent property of the aluminum oxide film that is the second insulation film is evaluated by taking density of the charge trapping site formed by the aluminum element diffused into the silicon dioxide film to a horizontal axis and taking a shift amount of the Vth to a longitudinal axis. It is seen from FIG. 8 that the shift amount of the Vth can be varied by controlling the density of the aluminum element to be diffused, that is, density of the charge trapping site with respect to the film thickness of each of the aluminum oxide films. Here, in view of decrease in the EOT of the gate insulation film, it is desirable that the film thickness of the aluminum oxide film is set to 30 nm or thinner, and more desirably it is set to 10 nm or thinner. In that case, in order to achieve a shift of the threshold voltage of 0.5V or higher, it is desirable that the aluminum element of 1×10¹² atoms per 1 cm² is contained, and more desirably the aluminum element of 5×10¹² or more atoms per 1 cm² is contained.

Further, in the case where the aluminum oxide film is used as a diffusion source of aluminum to the silicon dioxide film, density of the aluminum element contained in the aluminum oxide film becomes an upper limit of density of the aluminum element that can be diffused. For example, when estimated from FIG. 7 of Example 1 in the present invention, density of the aluminum element that becomes the upper limit is 5×10¹⁵ atoms/cm². However, the density of this upper limit is density enough to sufficiently obtain the Vth shift amount of the device even in the case where the aluminum oxide film of 0.5 nm is formed in FIG. 8, and there is no limitation to an electrical characteristic of the device in the present invention.

Next, effects that the film thickness of the silicon dioxide film that is the first insulation film is presented to a device property will be described. Here, a film thickness of the silicon dioxide film of the evaluated device is varied in the range of 3 nm to 10 nm, and an aluminum element is distributed into each device in the depth direction with a diffusion length of 3 nm. FIG. 9 is a drawing in which a film thickness dependent property of the silicon dioxide film, which is the first insulation film, relating to time variation in Vth when charge is written into the device is examined by respectively taking time and Vth to a horizontal axis and a longitudinal axis. In this regard, the Vth in the longitudinal axis is standardized with each initial Vth. Further, the time in the horizontal axis is time when the device is kept in a high temperature bath of 150° C. It is seen from FIG. 9 that the device having the film thickness of the silicon dioxide film in the range of 10 nm to 5 nm has excellent charge retention capability. For this reason, it can be said that there is no blocking of the retention capability so long as the film thickness of the silicon dioxide film becomes up to 5 nm and miniaturization thereof can thus be made. Therefore, the device having retention capability more than that in Conventional Example can be realized with about a half of the film thickness compared with Conventional Example. On the other hand, in the device having a film thickness of the silicon dioxide film of 3 nm, charge retention capability is lowered largely. This indicates that a leak protecting function of trapped charge is lowered with respect to the semiconductor substrate of the silicon dioxide film because an aluminum element at the same level as the film thickness of the silicon dioxide film is diffused. Thus, it is important that a diffusion length of the aluminum element to be diffused in the silicon dioxide film is controlled so as to be made thinner than the film thickness of the silicon dioxide film.

As described above, the features of Example 1 are as follows.

(1) An aluminum element that is a constituent element of the aluminum oxide film, which is the second insulation film, is contained in the silicon dioxide film that is the first insulation film by means of diffusion. This makes it possible to form a charge trapping site in the silicon dioxide film, and thus, a nonvolatile semiconductor memory device having both decrease in the EOT and high retention capability as compared with the prior art can be obtained.
(2) By controlling density of the aluminum element to be diffused in the silicon dioxide film and the film thickness of the aluminum oxide film, a predetermined shift amount of the Vth can be achieved.
(3) If a region in which no aluminum element is contained in a lowermost layer of the silicon dioxide film is ensured by means of control of a diffusion length of the aluminum element, a thinned silicon dioxide film can be made without deteriorating the charge retention capability.

### EXAMPLE 2

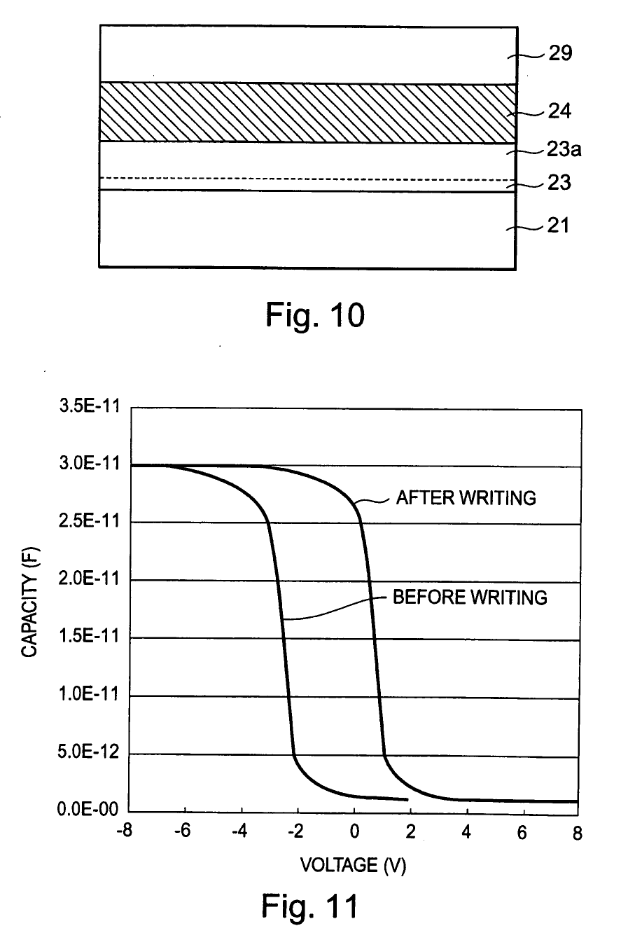

FIG. 10 is a sectional view of a gate insulation film portion of a nonvolatile semiconductor memory device according to Example 2 of the present invention. In the present example, a first insulation film 23, a second insulation film 24 and a third insulation film 29 are laminated on a silicon substrate 21. A charge trapping site containing region 23a into which an element constituting the second insulation film 24 is introduced as a charge trapping site is formed in the first insulation film 23. Points different from Example shown in FIG. 1(a) are that the second insulation film 24 is caused to crystallize and that the third insulation film 29 of an amorphous state is formed on the second insulation film. In this regard, in the present example, the second insulation film and the third insulation film are made of material of the same composition.

Hereinafter, a formation step of a gate insulation film in Example 2 will be described, but other steps are the same as those in Example 1.

A silicon dioxide film of 10 nm which is the first insulation film 23 is formed on the silicon substrate 21 by means of a thermal oxidation method. An aluminum oxide film is formed thereon as the second insulation film 24 by means of a MOCVD method. For example, an aluminum oxide film of 3 nm is formed by using Al (CH₃)₃ as organic metal material and H₂O as an oxidizing agent, and alternately supplying Al (CH₃)₃ and H₂O on the substrate subjected to heating at 300° C. Further, ozone may be used as the oxidizing agent. Moreover, an ALD method may be used by controlling partial pressure of the oxidizing agent to be introduced. Furthermore, a PVD method such as sputtering may be used. Further, a composition of aluminum and oxygen in aluminum oxide may be varied by controlling a flow ratio of the organic metal material and the oxidizing agent and oxygen partial pressure at sputtering. By varying the composition, density of aluminum to be diffused in the silicon dioxide film that is the first insulation film can be controlled. For example, by forming an aluminum oxide film having a composition of more aluminum than that in a stoichiometric composition of aluminum oxide, more aluminum element can be diffused.

Next, the aluminum element contained in the aluminum oxide film that is the second insulation film 24 is diffused in the silicon dioxide film that is the first insulation film 23 by means of thermal treatment, and the aluminum oxide film is caused to crystallize. Here, by causing it to crystallize, excess aluminum element contained in the aluminum oxide film can be diffused in the silicon dioxide film, and the charge trapping site containing region 23a containing the aluminum element of high density can be formed in the first insulation film 23 (silicon dioxide film). For example, thermal treatment at 900° C. or higher is implemented in the nitrogen atmosphere or the oxygen atmosphere for 10 or more seconds.

Next, an aluminum oxide film is formed on the crystallized aluminum oxide film as the third insulation film 29 by means of a MOCVD method. For example, an aluminum oxide film of 7 nm is formed by using Al (CH₃)₃ as the organic metal material and H₂O as the oxidizing agent and alternately supplying Al (CH₃)₃ and H₂O on the substrate subjected to heating at 300° C. Further, ozone may be used as the oxidizing agent. Moreover, an ALD method may be used by controlling partial pressure of the oxidizing agent to be introduced. Furthermore, a PVD method such as sputtering may be used.

Next, in order to improve a leak characteristic of this insulation film having a laminated structure, thermal treatment is implemented at temperature in which the aluminum element is not diffused in the silicon dioxide film and the aluminum oxide film formed on the crystallized aluminum oxide film does not crystallize. For example, it is implemented at a temperature range of 600° C. to 800° C. for a time range of 1 sec. to 30 sec. in the nitrogen atmosphere or the oxygen atmosphere.

An AlHfO film may be formed as the second or third insulation film in place of the aluminum oxide film. AlHfO can be formed by a MOCVD method or an ALD method using Al (CH₃)₃ and Hf[N(C₂H₅)₂]₄ as organic metal material, and H₂O or ozone as an oxidizing agent.

Further, an AlSiO film may be formed in place of the aluminum oxide film. AlSiO can be formed by a MOCVD method or an ALD method using Al (CH₃)₃ and HSi[N(CH₃)₂]₃ as organic metal material, and H₂O or ozone as an oxidizing agent.

Hereinafter, measured results of a property of the nonvolatile semiconductor memory device manufactured by Example 2 will be described.

FIG. 11 shows a capacity-voltage characteristic of the device obtained in Example 2 before and after writing. It is seen from FIG. 11 that a nonvolatile operation can be realized because the capacity-voltage characteristic is largely shifted before and after the writing.

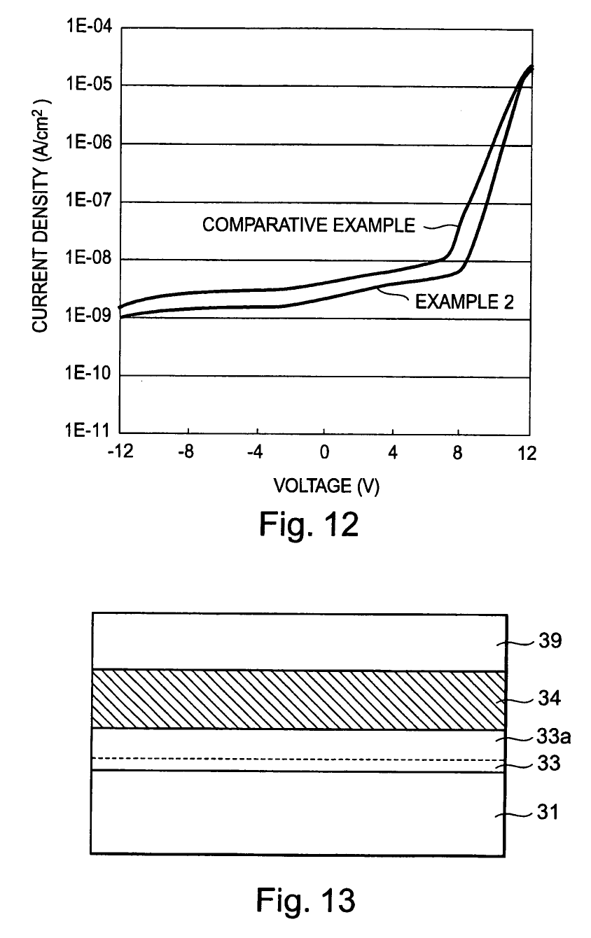

FIG. 12 shows a current-voltage characteristic of the device obtained in Example 2 at the writing. Further, it also shows a current-voltage characteristic of the device when the whole aluminum oxide film is caused to crystallize as Comparative Example. In FIG. 12, gate voltage and current density between a gate electrode and the substrate are respectively taken in a horizontal axis and a longitudinal axis. As is apparent from FIG. 12, in the device manufactured in Example 2, a leak characteristic is improved. This is because a leak through a grain boundary is inhibited by forming the aluminum oxide film of an amorphous structure. Thus, it is shown that deterioration of a retention characteristic due to a leak is inhibited in Example 2.

In this way, the feature of Example 2 is that a leak of charge caused by the grain boundary can be inhibited because the aluminum oxide film having an amorphous structure as the third insulation film exists between the gate electrode and the second insulation film even though the second insulation film crystallizes at a step of diffusing an aluminum element in the first insulation film. Thus, since a problem that a device property is deteriorated due to crystallization of the aluminum oxide film can be solved, more aluminum element can be formed at high thermal diffusion temperature.

### EXAMPLE 3

FIG. 13 is a sectional view of a gate insulation film portion of a nonvolatile semiconductor memory device according to Example 3 of the present invention. In the present example, a first insulation film 33, a second insulation film 34 and a third insulation film 39 are laminated on a silicon substrate 31. A charge trapping site containing region 33a into which an element constituting the second insulation film 34 is introduced as a charge trapping site is formed in the first insulation film 33. Points different from Example shown in FIG. 1(a) are that the second insulation film is caused to crystallize and that a third insulation film of an amorphous state is formed on the second insulation film. In this regard, in the present example, a constituent element of the second insulation film does not correspond with a constituent element of the third insulation film.

Hereinafter, a formation step of a gate insulation film in Example 3 will be described, but other steps are the same as those in Example 1.

A silicon dioxide film of 10 nm which is the first insulation film 33 is formed on the silicon substrate 31 by means of a thermal oxidation method. An aluminum oxide film is formed thereon as the second insulation film 34 by means of a MOCVD method. For example, an aluminum oxide film of 10 nm is formed by using Al (CH₃)₃ as organic metal material and H₂O as an oxidizing agent, and alternately supplying Al (CH₃)₃ and H₂O on the substrate subjected to heating at 300° C. Further, ozone may be used as the oxidizing agent. Moreover, an ALD method may be used by controlling partial pressure of the oxidizing agent to be introduced. Furthermore, a PVD method such as sputtering may be used. Further, a composition of aluminum and oxygen in aluminum oxide may be varied by controlling a flow ratio of the organic metal material and the oxidizing agent and oxygen partial pressure at sputtering. By varying the composition, density of aluminum to be diffused in the silicon dioxide film that is the first insulation film can be controlled. For example, by forming an aluminum oxide film having a composition of more aluminum than that in a stoichiometric composition of aluminum oxide, more aluminum element can be diffused.

Next, the aluminum element contained in the aluminum oxide film that is the second insulation film 34 is diffused in the silicon dioxide film that is the first insulation film 33 by means of thermal treatment, and the aluminum oxide film is caused to crystallize. For example, thermal treatment at 900° C. or higher is implemented in the nitrogen atmosphere or the oxygen atmosphere for 10 or more seconds.

Next, a silicon dioxide film to become a third insulation film 39 is formed on the second insulation film 34 (aluminum oxide film). For example, the silicon dioxide film of 10 nm is formed by means of a Low Pressure CVD (LPCVD) method. In this case, it is formed by setting substrate temperature to 800° C. and causing SiH₄ and N₂O to react under pressure of 32 Pa. Further, it may be formed by means of a plasma CVD method. In this case, it can be formed by setting substrate temperature to 200° C. and causing SiH₄ and N₂O to react in plasma.

Further, an AlHfO film may be formed in place of the aluminum oxide film. AlHfO can be formed by means of a MOCVD method or an ALD method using Al (CH₃)₃ and Hf[N(C₂H₅)₂]₄ as organic metal material and H₂O or ozone as an oxidizing agent. Moreover, an AlSiO film may be formed in place of the aluminum oxide film. AlSiO can be formed by a MOCVD method or an ALD method using Al (CH₃)₃ and HSi[N(CH₃)₂]₃ as organic metal material, and H₂O or ozone as an oxidizing agent.

Further, an amorphous AlHfO film may be formed in place of the silicon dioxide film to be formed on the crystallized aluminum oxide film. Moreover, an amorphous AlSiO film may be formed in place of the silicon dioxide film to be formed on the crystallized aluminum oxide film.

Hereinafter, measured results of a property of the device manufactured by Example 3 will be described.

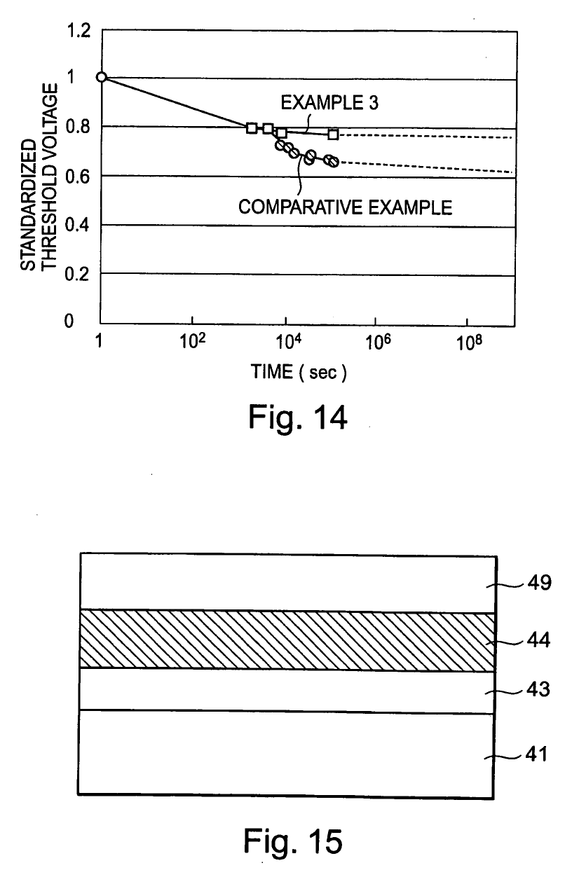

FIG. 14 is a drawing in which time variation in Vth of the device obtained by Example 3 when charge is written into the device is examined by respectively taking time and Vth to a horizontal axis and a longitudinal axis. Further, it also shows a charge retention characteristic of the device in which the whole aluminum oxide film is crystallized as Comparative Example. In this regard, the Vth in the longitudinal axis is standardized with each initial Vth. Moreover, the time in the horizontal axis is time when the device is kept in a high temperature bath of 150° C. It is seen from FIG. 14 that the retention characteristic is improved by providing the third insulation film of the amorphous structure. This is, as well as Example 2, because a leak through a grain boundary is inhibited by forming the silicon dioxide film of an amorphous structure.

In this way, the feature of Example 3 is that a leak of charge caused by the grain boundary can be inhibited and the retention characteristic can be improved because the third insulation film having an amorphous structure and a constituent element different from that of the second insulation film is formed even in the case where the second insulation film is crystallized at a step of diffusing an aluminum element in the first insulation film.

### COMPARATIVE EXAMPLE

FIG. 15 is a sectional view of a gate insulation film portion of Comparative Example. As shown in FIG. 15, a silicon dioxide film as a first insulation film 43, an aluminum oxide film as a second insulation film 44 and a silicon dioxide film as a third insulation film 49 are formed on a silicon substrate 41. However, it is different from Embodiments 2 and 3 shown in FIGS. 10 and 13 on the point that aluminum that is an element constituting the second insulation film 44 is not introduced in the first insulation film 43. In order to compare with this Comparative Example, a device having a region in which an aluminum element is contained in a silicon dioxide film that is a first insulation film is also manufactured on the basis of the present invention. A formation step of a gate insulation film in the present Comparative Example is the same as that in Example 3 except that the step of diffusing an aluminum element in the silicon dioxide film is not implemented.

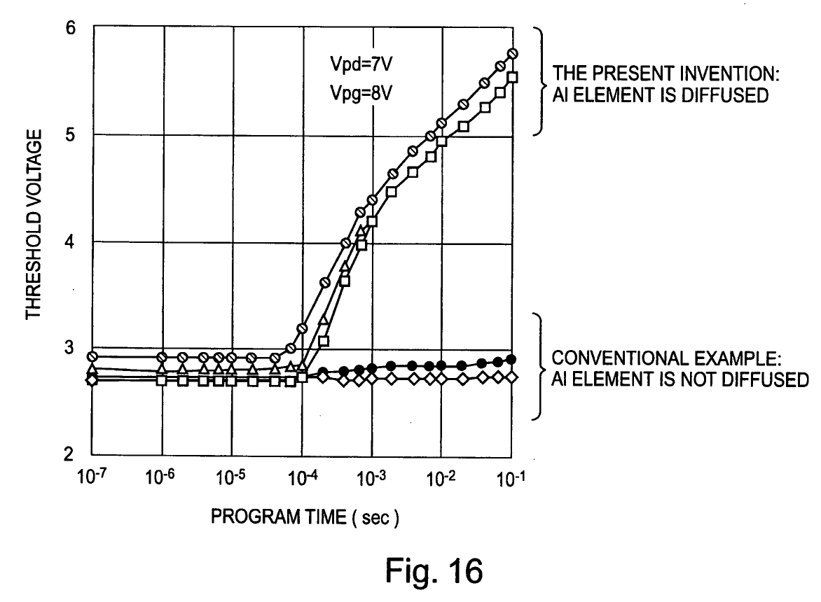

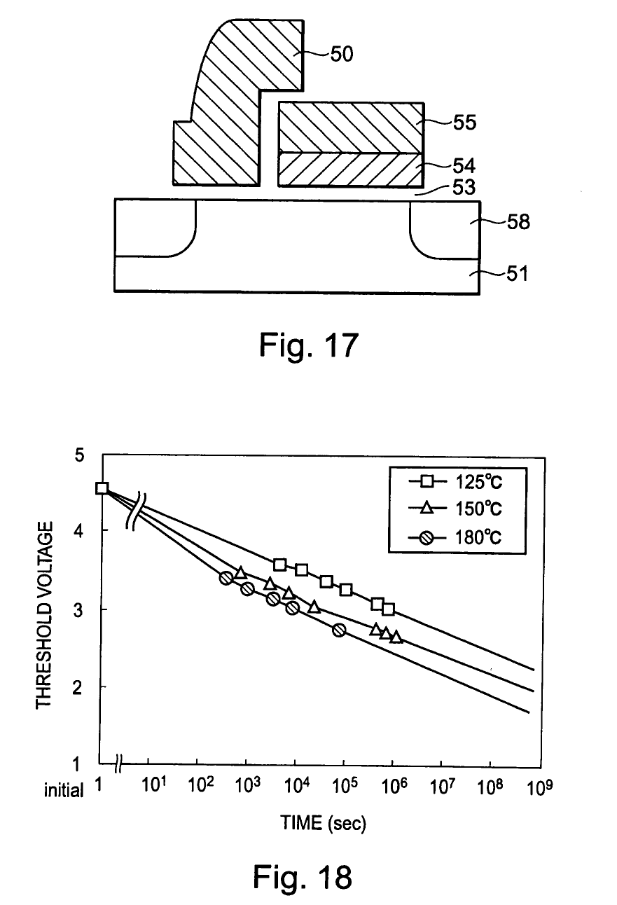

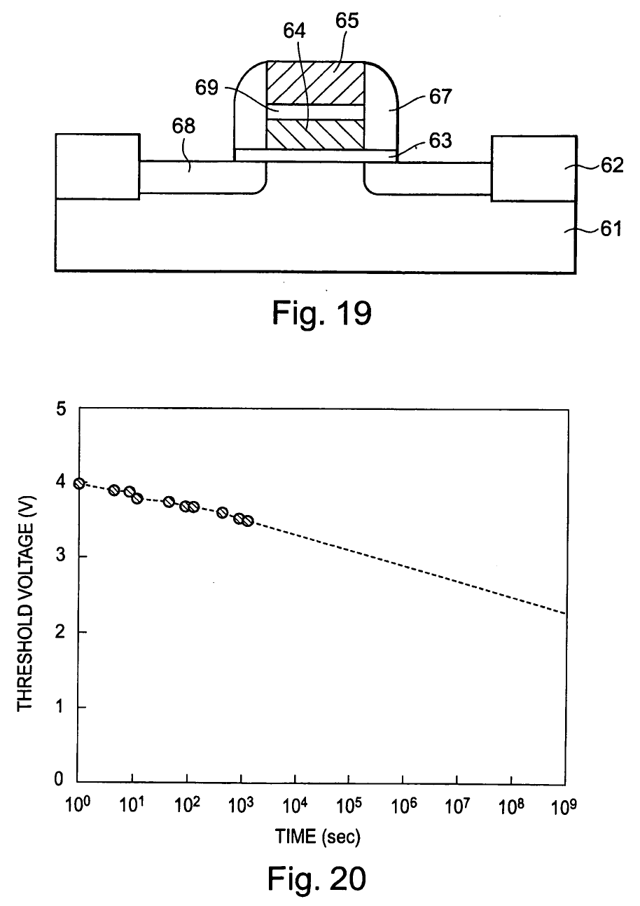

A writing characteristic of each of devices in which an aluminum element is diffused in a silicon dioxide film or not is shown in FIG. 16. A horizontal axis is accumulated time of a writing pulse (drain voltage 7V, gate voltage 8V), while a longitudinal axis is Vth. As is apparent from FIG. 16, no writing is carried out in the device in which no aluminum element is diffused in the silicon dioxide film, and a nonvolatile operation is not indicated. However, writing is carried out in the device in which the aluminum element is diffused. This result indicates that the charge trapping site of the device manufactured by the present invention is derived from the aluminum element diffused in the silicon dioxide film.

### INDUSTRIAL APPLICABILITY

The present invention can be applied to a nonvolatile semiconductor memory device. In particular, the present invention can be applied to a nonvolatile semiconductor memory device in which the nonvolatile semiconductor memory device has no floating gate, and charge trapping is carried out in a gate insulation film of an insulation film having a laminated structure. Since the charge retention characteristic of the nonvolatile semiconductor memory device can be improved by applying the present invention thereto, the present invention is extremely useful.

1. A nonvolatile semiconductor memory device comprising a plurality of nonvolatile memory devices, each nonvolatile memory device having a first insulation film and a second insulation film as a gate insulation film, the first insulation film being formed so as to contact with a surface of a semiconductor substrate, the second insulation film being formed so as to contact with the first insulation film,
wherein at least one element of elements that constitute the second insulation film is contained in at least a region of the first insulation film that contacts with the second insulation film as a trapping site for charge.

2. The nonvolatile semiconductor memory device as claimed in claim 1, wherein the element that constitutes the second insulation film and is contained in the first insulation film as the trapping site for charge (hereinafter, referred to as “trapping site element”) has density distribution in which density becomes lower toward a surface of the semiconductor substrate, and the trapping site element is not contained in a region of the first insulation film that contacts with the semiconductor substrate.

3. The nonvolatile semiconductor memory device as claimed in claim 1, wherein density of the trapping site element in the region where the first insulation film contacts with the second insulation film is 1×10¹² or more per 1 cm².

4. The nonvolatile semiconductor memory device as claimed in claim 1, wherein density distribution of the trapping site element substantially follows Gaussian distribution in which a maximum value exists in a region near the second insulation film.

5. The nonvolatile semiconductor memory device as claimed in claim 1, wherein the trapping site element is a metallic element.

6. The nonvolatile semiconductor memory device as claimed in claim 1, wherein the trapping site element is aluminum.

7. The nonvolatile semiconductor memory device as claimed in claim 1, wherein the first insulation film except the trapping site element constitutes a silicon dioxide film.

8. The nonvolatile semiconductor memory device as claimed in claim 1, wherein a film thickness of the first insulation film falls within a range between 3 nm and 20 nm, both inclusive.

9. The nonvolatile semiconductor memory device as claimed in claim 1, wherein the second insulation film is an insulation film containing aluminum.

10. The nonvolatile semiconductor memory device as claimed in claim 1, wherein the second insulation film is anyone of an aluminum oxide film, an aluminum hafnium oxide film and an aluminum silicon dioxide film.

11. The nonvolatile semiconductor memory device as claimed in claim 1, wherein the second insulation film is an aluminum oxide film having a film thickness of 30 nm or thinner, and density D of the trapping site element is 1×10¹² atoms<D<5×10¹⁵ atoms per 1 cm².

12. The nonvolatile semiconductor memory device as claimed in claim 1, wherein a third insulation film of an amorphous structure is laminated on the second insulation film so as to contact with the second insulation film.

13. The nonvolatile semiconductor memory device as claimed in claim 12, wherein the third insulation film is a silicon dioxide film, an aluminum oxide film, an aluminum hafnium oxide film or an aluminum silicon dioxide film.

14. The nonvolatile semiconductor memory device as claimed in claim 12, wherein the second insulation film has a crystal structure.

15. A method of manufacturing a nonvolatile semiconductor memory device, the nonvolatile semiconductor memory device including a plurality of nonvolatile memory devices, each nonvolatile memory device having a first insulation film and a second insulation film as a gate insulation film, the first insulation film being formed so as to contact with a surface of a semiconductor substrate, the second insulation film being formed so as to contact with the first insulation film, the method comprising:
forming a gate insulation film;
forming a gate electrode; and
forming a source/drain region,
wherein the forming the gate insulation film comprising:
(1) forming a first insulation film on the surface of the semiconductor substrate;
(2) forming a second insulation film on the first insulation film; and
(3) introducing an element that does not constitute the first insulation film but constitutes the second insulation film to the first insulation film.

16. The method as claimed in claim 15, wherein the (3) step includes diffusing the element from the second insulation film to the first insulation film by thermal treatment.

17. The method as claimed in claim 16, wherein the (3) step is carried out at temperature between 700° C. and 1,200° C., both inclusive.

18. The method as claimed in claim 15, wherein the second insulation film is anyone of an aluminum oxide film, an aluminum hafnium oxide film and an aluminum silicon dioxide film, and the (2) step uses a Metal Organic Chemical Vapor Deposition (MOCVD) method, an Atomic Layer Deposition (ALD) method or a sputtering method.

19. The method as claimed in claim 18, wherein in the (2) step, the film formation is carried out so that aluminum more than stoichiometric composition is contained.

20. A method of manufacturing a nonvolatile semiconductor memory device, the nonvolatile semiconductor memory device including a plurality of nonvolatile memory devices, each nonvolatile memory device having a first insulation film and a second insulation film as a gate insulation film, the first insulation film being formed so as to contact with a surface of a semiconductor substrate, the second insulation film being formed so as to contact with the first insulation film, the method comprising:
forming a gate insulation film;
forming a gate electrode; and
forming a source/drain region,
wherein the forming the gate insulation film comprising:
(1′) forming a first insulation film on the surface of the semiconductor substrate; and
(2′) forming a second insulation film on the first insulation film by a spattering method, and introducing an element that does not constitute the first insulation film but constitutes the second insulation film into the first insulation film.

21. The method as claimed in claim 20, wherein the second insulation film is anyone of an aluminum oxide film, an aluminum hafnium oxide film and an aluminum silicon dioxide film, and the element introduced into the first insulation film is aluminum.

22. The method as claimed in claim 20, wherein the semiconductor substrate is a silicon substrate, and the (1′) step is a step of forming a silicon dioxide film by thermal oxidation.

23. The method as claimed in claim 20, wherein the forming the gate insulation film further includes, after the (2′) step, forming a third insulation film of an amorphous structure on the second insulation film.

24. The method as claimed in claim 15, wherein the semiconductor substrate is a silicon substrate, and the (1) step is a step of forming a silicon dioxide film by thermal oxidation.

25. The method as claimed in claim 15, wherein the forming the gate insulation film further includes, after the (3) step, forming a third insulation film of an amorphous structure on the second insulation film.
